(19) United States
(12) Patent Application Publication
(10) Pub. No.: US 2014/0112429 A1
(43) Pub. Date: Apr. 24, 2014

(54) Low Voltage Register File Cell Structure

(71) Applicant: APPLE INC., Cupertino, CA (US)

(72) Inventors: Ajay Bhatia, Saratoga, CA (US); Greg M. Hess, Mountain View, CA (US); Sanjay P. Zambare, Sunnyvale, CA (US)

(73) Assignee: APPLE INC., Cupertino, CA (US)

(21) Appl. No.: 13/658,115

(22) Filed: Oct. 23, 2012

(51) Int. Cl. G11C 19/28

(52) U.S. Cl. 377/67

(57) ABSTRACT

A register file cell structure to enable lower voltage writes is disclosed. In one embodiment, a register file includes a state element made up of two cross-coupled inverters. Each of the inverters includes a p-channel metal oxide semiconductor (PMOS) transistor having a source terminal coupled to a virtual voltage node. One or more PMOS transistors are coupled in series between the virtual voltage node and a global voltage node. Each of the one or more PMOS transistors includes a gate terminal that is hardwired to a ground node, and thus these devices remain active when power is applied to the global voltage node. The presence of the one or more PMOS devices coupled between the virtual and global voltage nodes results in the ability to overwrite contents stored in the state element at lower voltages than otherwise attainable without the one or more PMOS devices.

### BACKGROUND

1. Technical Field

This disclosure relates to electronic circuits, and more particularly, to circuits used to implement register files.

2. Description of the Related Art

Many integrated circuits (IC's) utilize register files for temporary storage of data. For example, processors utilize register files to store operands for performing operations and for storing results of those operations. The number of registers used may vary from one type of processor to another. Typically, registers may be at the top of a memory hierarchy and thus the closest memory to an execution unit of a processor.

A register file may be implemented using a number of bit cells. Each register may include a certain number of bit cells, and a typical register file may include a number of registers. The type of circuitry used to implement bit cells for a register file may vary with the application. Factors that can affect the type of circuits chosen for bit cells may include speed, power consumption, area consumption, and so forth.

### SUMMARY OF THE DISCLOSURE

A register file cell structure to enable lower voltage writes is disclosed. In one embodiment, a register file bit cell includes a state element made up of two cross-coupled inverters. Each of the inverters includes a p-channel metal oxide semiconductor (PMOS) transistor having a source terminal coupled to a virtual voltage node. One or more PMOS transistors are coupled in series between the virtual voltage node and a global voltage node. Each of the one or more PMOS transistors includes a gate terminal that is hardwired to a ground node, and thus these devices remain active when power is applied to the global voltage node. The presence of the one or more PMOS devices coupled between the virtual and global voltage nodes results in the ability to overwrite contents stored in the state element at lower voltages than otherwise attainable without the one or more PMOS devices.

In one embodiment, a register filed includes M bit cells subdivided into groups (or subset) of N bit cells. Each of the N bit cells in a given group includes a plurality of cross-coupled inverters each coupled to receive power from a virtual voltage node. Each of the groups of bit cells includes a virtual voltage node that is exclusive to that particular group. Each of the groups of bit cells also includes one or more PMOS transistors coupled in series between its respective virtual voltage node and a global voltage node that is coupled to all of the groups. The PMOS transistors coupled between the virtual voltage node of each group and the global voltage node are configured to remain active whenever power is applied to the global voltage node.

### BRIEF DESCRIPTION OF THE DRAWINGS

Other aspects of the disclosure will become apparent upon reading the following detailed description and upon reference to the accompanying drawings in which:

FIG. 1 is a simplified block diagram of one embodiment of an integrated circuit (IC).

FIG. 2 is a simplified block diagram of one embodiment of a register file.

FIG. 3 is a schematic diagram of one embodiment of a subset of bit cells in a register file.

FIG. 4 is a block diagram of one embodiment of an exemplary system.

While the subject matter disclosed herein is susceptible to various modifications and alternative forms, specific embodiments thereof are shown by way of example in the drawings and will herein be described in detail. It should be understood, however, that the drawings and description thereto are not intended to be limiting to the particular form disclosed, but, on the contrary, is to cover all modifications, equivalents, and alternatives falling within the spirit and scope of the present disclosure as defined by the appended claims.

### DETAILED DESCRIPTION

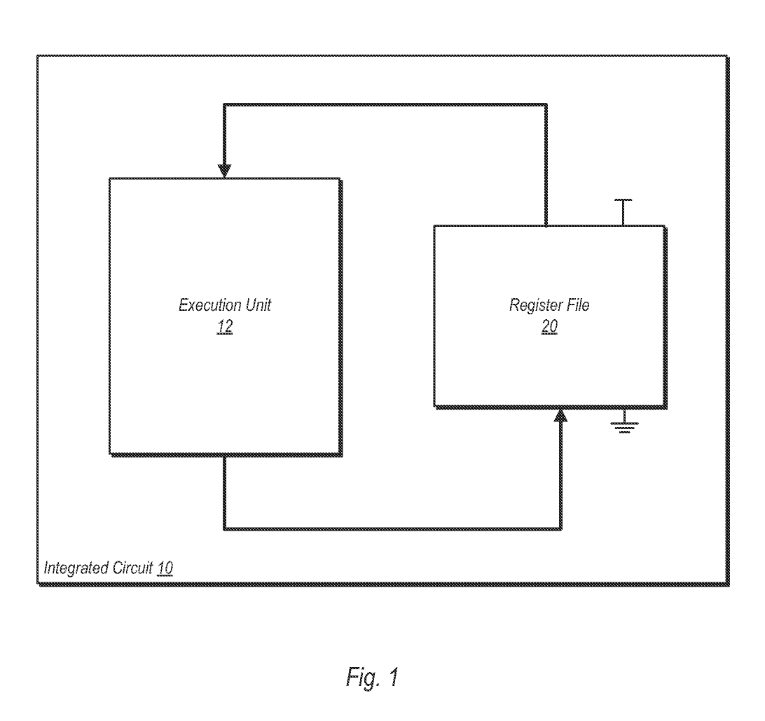

Turning now to FIG. 1, a block diagram of one embodiment of an integrated circuit (IC) is shown. IC 10 in the embodiment shown is an exemplary embodiment, and thus does not necessarily illustrate all components that may be present. Furthermore, while FIG. 1 illustrates one exemplary application of a register file, it is noted that this example is not intended to be limiting. On the contrary, the various embodiments of a register file discussed below may be used in a wide variety of applications not explicitly discussed herein.

In the embodiment shown, IC 10 is a processor including execution unit 21 and register file 20. Although not shown here, IC 10 may also include other agents, such as one or more cache memories, a load/store unit, branch prediction/determination mechanisms, re-ordering buffers, a retirement unit, and other agents used to support processor operation. Execution unit 12 in the embodiment shown is configured to execute instructions of a software program. Operands used in the execution of instructions may be provided from register file 20. The operands may be received from another unit in IC 10, such as a load/store unit. Results from the execution of instructions may be received by register file 20 from execution unit 12. These results may be committed and written back to memory by a load/store unit, and may also be written to one or more cache memories.

Register file 20 in the embodiment shown includes a number of registers. Among the included registers may be those defined by the architecture of the processor implemented on IC 10. Copies of the architected registers may also be provided to store speculative states resulting from the speculative execution of instructions. Similarly, copies of the architected registers may be provided to store operands to be used in the speculative execution of instructions. In some embodiments, register renaming may be used to determine specific ones of the registers are considered to be architected registers, and which are considered to be extra registers during a given operational cycle.

It is noted that while the various circuit embodiments described below are in the context of registers, and more particularly, in the context of architected registers, such disclosure is exemplary and is not intended to be limiting. The circuitry described below may be used with any type of memory having a dedicated write port, a dedicated read port, or both.

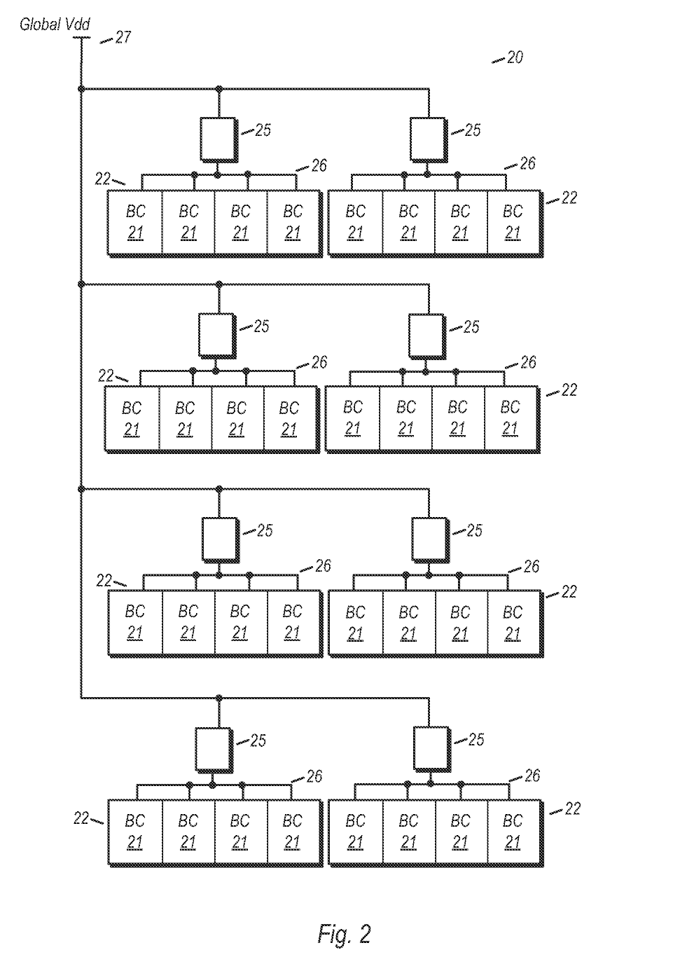

Turning now to FIG. 2, a block diagram of an exemplary register file is shown. Register file 20 in the embodiment shown includes a number of bitcells 21. The bitcells 21 of register file 20 are divided into subsets 22. Generally speaking, register file 20 in the embodiment shown includes a total of M bitcells 21, while each subset 22 in the embodiment shown includes N bitcells 21. M and N are integer values, and may vary from one embodiment to the next.

In the embodiment shown, each of the subsets 22 is associated with a transistor stack 25. Furthermore, each of the subsets 22 is coupled to virtual voltage node 26. The virtual voltage node 26 for each of the subsets is coupled to receive voltage from a global voltage node 27. As defined herein, a virtual voltage node is a voltage node that is coupled to bitcells 21 of a particular subset 22, exclusive of bitcells 21 of any other subset 22. Thus, a given instance of a virtual voltage node as defined herein may provide an operating voltage to selected ones of bitcells 21 (in this case, within a corresponding subset 22), but is not coupled to provide an operating voltage to all bitcells 21 of register file 20. A virtual voltage node may further be defined herein as a voltage node that receives its voltage through one or more transistors coupled to another voltage node. A global voltage node as defined herein is a voltage node that is coupled, through transistors, to the virtual voltage node 26 of each of the subsets 22 of register file 20. It is further noted that a global voltage node as defined herein may be coupled to other circuitry external to register file 20, although this is not necessarily the case for all embodiments. A global voltage node as defined herein may be coupled directly to a power supply, a voltage regulator, or other portion of a power distribution system on an IC upon which register file 20 is implemented.

Each transistor stack 25 in the embodiment shown may include one or more transistors coupled in series between global voltage node 27 and its corresponding virtual voltage node 26. In one embodiment, a transistor stack 25 may include at least one p-channel metal oxide semiconductor (PMOS) transistor, and in some embodiments, more than one PMOS transistor may be included. The one or more PMOS transistors may be configured to remain active during operation, e.g., whenever the specified operating voltage is applied to the global voltage node.

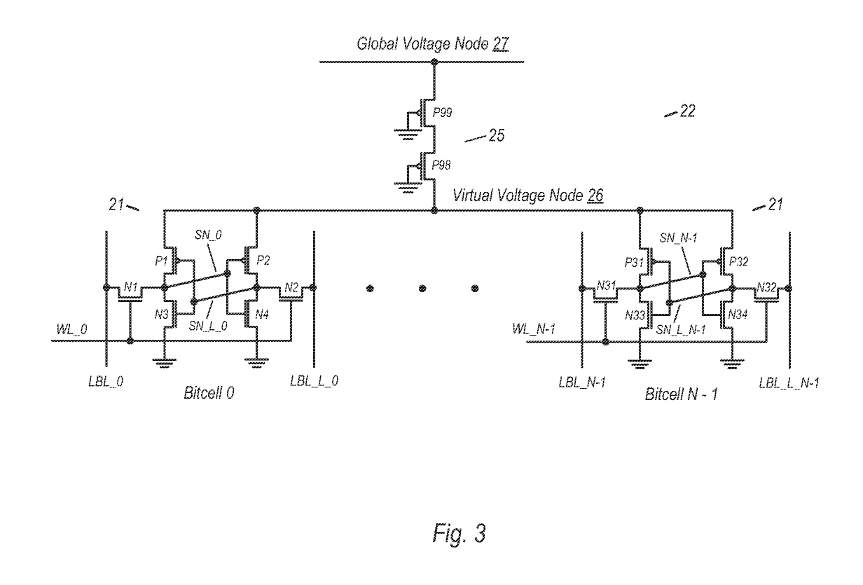

FIG. 3 is a schematic diagram illustrating one embodiment of a subset of bitcells included in a register file. In the embodiment shown, subset 22 includes N bitcells 21, although only two (Bitcell 0 and Bitcell N-1) are shown here for the sake of simplicity. Each bitcell 21 in the embodiment shown includes a state element made up of two cross-coupled inverters. For example, in Bitcell 0, a first inverter includes transistors P1 and N3, while a second inverter includes transistors P2 and N4. The output of the first inverter is storage node SN_{—}0, and is coupled to the input of the second inverter. Similarly, the output of the second inverter is a complementary storage node, SN_L_{—}0, and is coupled to the input of the first inverter.

Each bitcell 21 also includes a pair of passgate transistors to couple the storage nodes to local bit lines. For example, Bitcell 0 includes a first passgate transistor (N1) configured to couple the first storage node, SN_{—}0, to a first local bit line, LBL_{—}0. Bitcell 0 also includes a second passgate transistors, N2, configured to couple the second storage node, SN_L_{—}0, to a second local bit line, LBL_L_{—}0. Transistors N1 and N2 may be activated responsive to activation of a word line, WL_{—}0, coupled to each of their respective gate terminals. Writes to each bit cell 21 may be accomplished by activating the passgate transistors to convey data from respectively coupled local bit lines to the storage nodes. In some embodiments, reads may also be accomplished by activating passgate transistors of the bitcells to be read and allowing the states of the storage nodes to propagate to the local bit lines. However, embodiments are possible and contemplated wherein additional circuitry (not shown here) is provided to read the bitcells without activation of the illustrated pass-gates.

Power may be received by the inverters of each bitcell 21 through source terminals of their respective PMOS transistors. For example, in Bitcell 0, the source terminals of P1 and P2 are coupled to virtual voltage node 26 (which is exclusive to the illustrated instance of subset 22). Power may be provided to virtual voltage node 26 from global voltage node 27 via transistor stack 25. In this embodiment, transistor stack 25 includes two PMOS transistors, P98 and P99, coupled in series between virtual voltage node 26 and global voltage node 27. Respective gate terminals of P98 and P99 are hardwired to a ground (or reference) node in the illustrated embodiment. Thus, transistors P98 and P99 may remain active when the power is applied as specified (e.g., as the specified voltage) to global voltage node 27.

It is noted that while the illustrated embodiment includes two transistors coupled in series between virtual voltage node, the number of transistors in a transistor stack 25 may vary from one embodiment to the next. A transistor stack may be implemented with only a single transistor in some embodiments, while more than two transistors per transistor stack may be provided in other embodiments.

The utilization of transistor stack 25 as shown in FIG. 3 (as well as in other embodiments) may provide various advantages. One advantage of providing the transistor stack 25 and thus separating the virtual voltage node from the global voltage node is to allow a lower write voltage. In particular, the voltage needed to overwrite the contents of a given bitcell 21 may be lower in embodiments utilizing a variation of the power directly from the global voltage node, as the drive strength of the PMOS transistors in the inverters is reduced. Another advantage that may be obtained by utilizing a transistor stack is that the size of the devices used to implement the pass-gates may be reduced. Yet another advantage that may be obtained by the illustrated configuration is the reduction of leakage currents through the bitcells, which may in turn result in significant power savings. Since a single transistor stack may be utilized for a number of bitcells in a given subset, the advantages described above may be obtained with only a small amount of overhead.

Each of the PMOS transistors in transistor stack 25 in the embodiment shown are configured to operate similar to a linear resistor when their respective gate terminals are tied to a reference node (e.g., Vss or ground). More particularly, each of the transistors in transistor stack 25 may operate in the linear region. By adding more effective resistance between global voltage node 27 and the PMOS devices of the inverters in each bitcell (e.g., P1 and P2 in bitcell 0), these PMOS devices become weaker. By weakening the pull-up strength of the PMOS devices of the inverters, it becomes easier for a logic 0 resulting from an NMOS device to pull down against a corresponding PMOS device. Thus, a logic 0 may be written into a bitcell easier, at a lower voltage, and faster in comparison to bitcells where transistor stack 25 is not present.

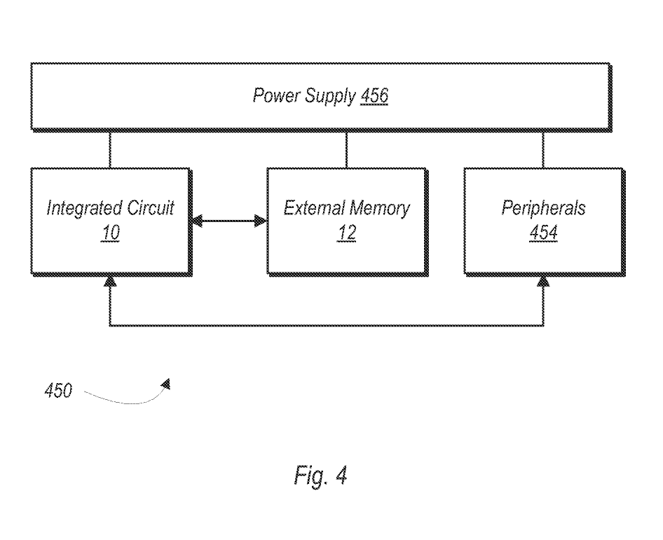

Turning next to FIG. 4, a block diagram of one embodiment of a system 350 is shown. In the illustrated embodiment, the system 450 includes at least one instance of the integrated circuit 10 coupled to external memory 12 (e.g. the memory 12A-12B in FIG. 1). The integrated circuit 10 is coupled to one or more peripherals 454 and the external memory 12. A power supply 456 is also provided which supplies the supply voltages to the integrated circuit 10 as well as one or more supply voltages to the memory 12 and/or the peripherals 454. In some embodiments, more than one instance of the integrated circuit 10 may be included (and more than one external memory 12 may be included as well).

The peripherals 454 may include any desired circuitry, depending on the type of system 450. For example, in one embodiment, the system 450 may be a mobile device (e.g. personal digital assistant (PDA), smart phone, etc.) and the peripherals 454 may include devices for various types of wireless communication, such as WiFi, Bluetooth, cellular, global positioning system, etc. The peripherals 454 may also include additional storage, including RAM storage, solid state storage, or disk storage. The peripherals 454 may include user interface devices such as a display screen, including touch display screens or multitouch display screens, keyboard or other input devices, microphones, speakers, etc. In other embodiments, the system 450 may be any type of computing system (e.g. desktop personal computer, laptop, workstation, net top etc.).

Numerous variations and modifications will become apparent to those skilled in the art once the above disclosure is fully appreciated. It is intended that the following claims be interpreted to embrace all such variations and modifications.

1. A register file comprising:
a plurality of bit cells subdivided into subsets of bit cells each including two or more of the plurality of bit cells, wherein each of the bit cells comprises a pair of cross-coupled inverters, wherein bit cells of each subset are coupled to receive a supply voltage from a virtual voltage node unique to that subset, and wherein each of the subsets includes a plurality of p-channel metal oxide semiconductor (PMOS) transistors coupled in series between the virtual voltage node of that subset and a global voltage node coupled to each of the subsets, wherein a gate terminal of each of the PMOS transistors is hardwired to a reference node such that each of the PMOS transistors remains active during operation of the register file, and wherein each of the cross-coupled inverters is coupled to receive power from the virtual voltage node.

2. The register file as recited in claim 1, wherein the plurality of PMOS transistors are configured to pull a voltage present on the virtual voltage node toward a voltage present on the global voltage node.

3. The register file as recited in claim 1, wherein the plurality of PMOS transistors in each subset includes a first PMOS transistor and a second PMOS transistor, wherein the first PMOS transistor is coupled between the virtual voltage node of that subset and the second transistor, and wherein the second PMOS transistor is coupled between the first PMOS transistor and the global voltage node.

4. The register file as recited in claim 1, wherein each of the plurality of bit cells in a subset includes a state element comprising first inverter and a second inverter coupled to receive power from its corresponding virtual voltage node, wherein an output of the first inverter comprises a first storage node and an output of the second inverter comprises a second storage node.

5. The register file as recited in claim 4, wherein each of the plurality of bit cells includes a first passgate transistor coupled between the first storage node and a first bit line and a second passgate transistor coupled between the second storage node and a second bit line.

6. A register file bit cell comprising:
a state element including a pair of cross-coupled inverters each coupled to receive power from a virtual voltage node; and
a plurality of p-channel metal oxide semiconductor (PMOS) transistors coupled in series between a supply voltage node and the virtual voltage node, wherein each of the plurality of PMOS transistors includes a gate terminal hardwired to a reference node such that it is held in an active state during operation.

7. The register file bit cell as recited in claim 6, wherein the plurality of PMOS transistors includes a first and second PMOS transistors coupled in series between the supply voltage node and the virtual voltage node.

8. The register file as recited in claim 7, wherein the first and second PMOS transistors are configured to pull a voltage present on the virtual voltage node toward a voltage present on the global voltage node.

9. The register file as recited in claim 6, wherein a first one of the cross-coupled inverters is configured to drive a first storage node, and wherein a second one of the cross-coupled inverters is configured to drive a second storage node that is a complement of the first storage node.

10. The register file as recited in claim 9, further comprising a first passgate coupled between the first storage node and a first local bit line, and a second passgate coupled between the second storage node and a second bit line.

11. A circuit comprising:
a first plurality of bit cells, wherein the first plurality of bit cells is a subset of a second plurality of bit cells comprising a register file, and wherein each of the first plurality of bit cells includes a pair of cross-coupled inverters coupled to a virtual voltage node exclusive to the first plurality of bit cells; and
a transistor stack having a plurality of transistors coupled in series between the virtual voltage node and a global voltage node, wherein the transistor stack includes one or more transistors hardwired to remain active when power is applied to the global voltage node.

12. The circuit as recited in claim 11, wherein the transistor stack includes a first and second p-channel metal oxide semiconductor (PMOS) transistors coupled in series between the virtual voltage node and the global voltage node.

13. The circuit as recited in claim 12, wherein each of the first and second PMOS transistors includes a respective gate terminal coupled to a ground node.

14. The circuit as recited in claim 11, wherein the first and second PMOS transistors are configured to, when active, reduce a drive strength of PMOS transistors in each of the first plurality of bit cells.

15. The circuit as recited in claim 11, wherein the first and second PMOS transistors are configured to, when active, pull a voltage present on the virtual voltage node toward a voltage present on the global voltage node.

16. A register file comprising:
a plurality of bit cells arranged in M subsets each having N bit cells, wherein each of the N bit cells includes:
a first inverter and a second inverter, wherein an output of the first inverter is coupled to an input of the second inverter and wherein an output of the second inverter is coupled to an input of the first inverter, wherein each of the first and second inverters are coupled to receive power from a virtual voltage node that is unique to that subset of the N bit cells; and
wherein each of the M subsets includes a transistor stack having a plurality of transistors coupled in series between the virtual voltage node of that subset and a global voltage node, wherein the transistor stack is configured to pull a voltage on the virtual voltage node toward a voltage present on the global voltage node.

17. The register file as recited in claim 16, wherein each of the M subsets is coupled to receive power from the global voltage node through a corresponding transistor stack coupled to the virtual voltage node of that subset, and wherein the transistor stack of each of the M subsets is configured to remain active when power is applied to the global voltage node.

18. The register file as recited in claim 16, wherein the transistor stack for each of the M subsets includes one or more p-channel metal oxide semiconductor (PMOS) transistors coupled between the virtual voltage node of that subset and the global voltage node.

19. The register file as recited in claim 18, wherein each of the one or more PMOS transistors in a given one of the transistor stacks includes a gate terminal coupled to a ground node.

20. The register file as recited in claim 19, wherein the one or more PMOS transistors are configured to, when active, reduce respective drive strengths of PMOS transistors in the first and second inverters of each the N bit cells of a corresponding one of the M subsets.

21. An integrated circuit comprising:
an execution unit configured to execute instructions;
a register file configured to store operands for instructions to be executed by the execution unit, and further configured to store results of instructions executed by the execution unit, wherein the register file includes:
a plurality of bit cells arranged in M subsets each having N bit cells, wherein each of the N bit cells includes:
a first inverter and a second inverter, wherein an output of the first inverter is coupled to an input of the second inverter and wherein an output of the second inverter is coupled to an input of the first inverter, wherein each of the first and second inverters are coupled to receive power from a virtual voltage node that is unique to that subset of the N bit cells; and
wherein each of the M subsets includes a transistor stack coupled between the virtual voltage node of that subset and a global voltage node, the transistor stack comprising a plurality of series-coupled transistors, wherein the transistor stack is configured to pull a voltage on the virtual voltage node toward a voltage present on the global voltage node.

22. The integrated circuit as recited in claim 21, wherein the transistor stack for each of the M subsets includes first and second p-channel metal oxide semiconductor (PMOS) transistors coupled in series between the virtual voltage node of that subset and the global voltage node.

23. The integrated circuit as recited in claim 22, wherein the first and second PMOS transistors of each of the transistor stack for each subset include respective gate terminals hardwired to a ground node.

24. The integrated circuit as recited in claim 23, wherein the first and second PMOS transistors associated with each of the M subsets are configured to, when active, reduce respective drive strengths of PMOS transistors in the first and second inverters of each the N bit cells in that one of the M subsets.
